(19) United States
(12) Patent Application Publication
(10) Pub. No.: US 2014/0048994 A1
(43) Pub. Date: Feb. 20, 2014

(54) Non-Contact Substrate Chuck and Vertical Type Substrate Supporting Apparatus Using the Same

(71) Applicant: SCIENTECH CORP., Taipei City (TW)

(72) Inventors: Wen-Ping TSAI, Taipei City (TW); Wei-Chen LI, Taipei City (TW)

(73) Assignee: SCIENTECH CORP., Taipei City (TW)

(21) Appl. No.: 13/858,633

(22) Filed: Apr. 8, 2013

(30) Foreign Application Priority Data
Aug. 14, 2012 (TW) 101129339

(51) Int. Cl. H01L 21/683

(52) U.S. Cl. CPC H01L 21/6838
USPC 269/21

(57) ABSTRACT

A non-contact substrate chuck applies to sucking a substrate and comprises a first plate-like element, a second plate-like element paralleled the first plate-like element and a sucking element, wherein through holes of the first plate-like element and the second plate-like element jointly form a channel where the sucking element is accommodated. The chuck lets gas flow through a gas inlet of the sucking element toward the substrate to form a gap between an active surface of the substrate and a first surface of the first plate-like element. At least one side of the substrate is positioned by positioning protrusions of the first plate-like element. A least possible number of supporting points are used and arranged around the sides of the substrate without touching the substrate surface to prevent the substrate surface from being damaged. The present invention also discloses a vertical-type substrate supporting apparatus using the abovementioned chuck.

### BACKGROUND OF THE INVENTION

1. Field of the Invention

The present invention relates to a substrate chuck technology, particularly to a non-contact substrate chuck and a vertical type substrate supporting apparatus using the same, which apply to wet chemical processes.

2. Description of the Related Art

In wet chemical processes, a substrate is soaked in different chemical liquids to fabricate multilayer circuits step by step. In the past procedure, substrates are mainly transported horizontally. Limited by the fabrication environment, a substrate can only be held from the positive face thereof in some processes. However, fragility or other factors may hinder a substrate from being held in the conventional ways in some cases. For example, in the case that the positive face of a substrate has circuit patterns apt to be damaged, the substrate cannot be held via sucking the positive face thereof lest the circuit patterns be affected and the operation thereof be impaired.

### SUMMARY OF THE INVENTION

One objective of the present invention is to provide a non-contact substrate chuck and a vertical type substrate supporting apparatus using the same to overcome the abovementioned problems, wherein the substrate chuck does not contact the surface of the substrate, and wherein the substrate chuck uses a least possible number of supporting points arranged along the sides of the substrate to position the substrate, whereby the surface of the substrate is exempted from being damaged.

To achieve the abovementioned objective, one embodiment of the present invention proposes a non-contact substrate chuck, which is used to suck and hold a substrate and comprises a first plate-like element including a first through hole penetrating the first plate-like element and a plurality of positioning protrusions arranged on a first surface of the first plate-like element; a second plate-like element arranged parallel to the first plate-like element and on a second surface of the first plate-like element and including a second through hole penetrating the second plate-like element and cooperating with the first through hole to form a channel; and a sucking element arranged inside the channel, wherein an active surface of the substrate faces the first surface of the first plate-like element, and wherein the non-contact substrate chuck lets gas flow through a gas inlet of the sucking element toward the substrate to form a gap between the active surface of the substrate and the first surface, and wherein at least one side of the substrate is positioned by the plurality of positioning protrusions.

Another embodiment of the present invention proposes a vertical type substrate supporting apparatus, which comprises the abovementioned non-contact substrate chuck and a fixture arranged on one side near the first plate-like element of the non-contact substrate chuck and separated from the non-contact substrate chuck by a first spacing, wherein while the first spacing between the fixture and the non-contact substrate chuck is decreased to a second spacing, the fixture moves the substrate to or off the first plate-like element of the non-contact substrate chuck.

Yet another embodiment of the present invention proposes a non-contact substrate chuck, which is used to suck and hold a substrate and comprises a first plate-like element including a first through hole penetrating the first plate-like element and a plurality of positioning protrusions arranged on a first surface of the first plate-like element; a second plate-like element arranged parallel to the first plate-like element and on a second surface of the first plate-like element and including a second through hole penetrating the second plate-like element and cooperating with the first through hole to form a channel; and a sucking element arranged inside the channel, wherein a surface of the substrate faces the first surface of the first plate-like element, and wherein the non-contact substrate chuck lets gas flow through a gas inlet of the sucking element toward the substrate to form a gap between the surface of the substrate and the first surface, and wherein at least one side of the substrate is positioned by the plurality of positioning protrusions.

A further embodiment of the present invention proposes a vertical type substrate supporting apparatus, which comprises the abovementioned non-contact substrate chuck and a fixture arranged on one side near the first plate-like element of the non-contact substrate chuck and separated from the non-contact substrate chuck by a first spacing, wherein while the first spacing between the fixture and the non-contact substrate chuck is decreased to a second spacing, the fixture moves the substrate to or off the first plate-like element of the non-contact substrate chuck.

Below, embodiments are described in detail in cooperation with the attached drawings to make easily understood the objectives, technical contents, characteristics and accomplishments of the present invention.

### BRIEF DESCRIPTION OF THE DRAWINGS

FIG. 1 is a diagram schematically showing a non-contact substrate chuck according to one embodiment of the present invention;

FIG. 2 is a side view schematically showing a non-contact substrate chuck according to one embodiment of the present invention;

FIG. 3A is a side view schematically showing the assembled components of a non-contact substrate chuck according to one embodiment of the present invention;

FIG. 3B is a locally enlarged view of FIG. 3A;

FIG. 4 is a diagram schematically showing a non-contact substrate chuck according to another embodiment of the present invention;

FIG. 5A and FIG. 5B are side views of a vertical type substrate supporting apparatus according to yet another embodiment of the present invention; and

FIG. 6A and FIG. 6B are side views of a vertical type substrate supporting apparatus according to a further embodiment of the present invention.

### DETAILED DESCRIPTION OF THE INVENTION

The present invention is described in detail with embodiments. However, it should be noted that these embodiments are only to exemplify the present invention but not to limit the scope of the present invention.

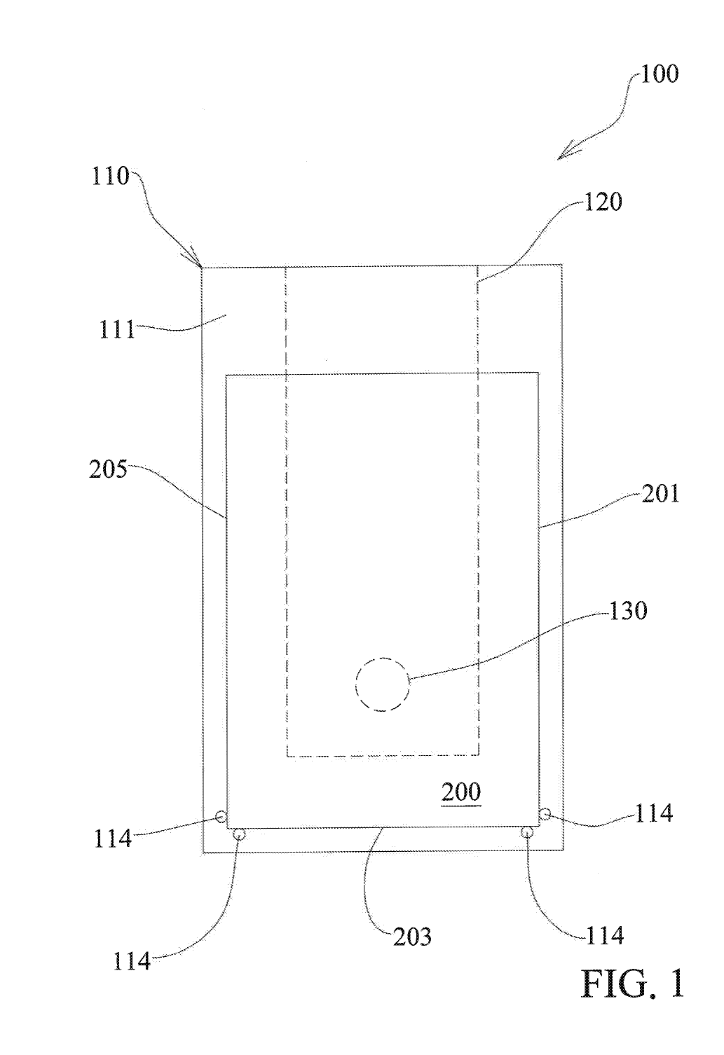

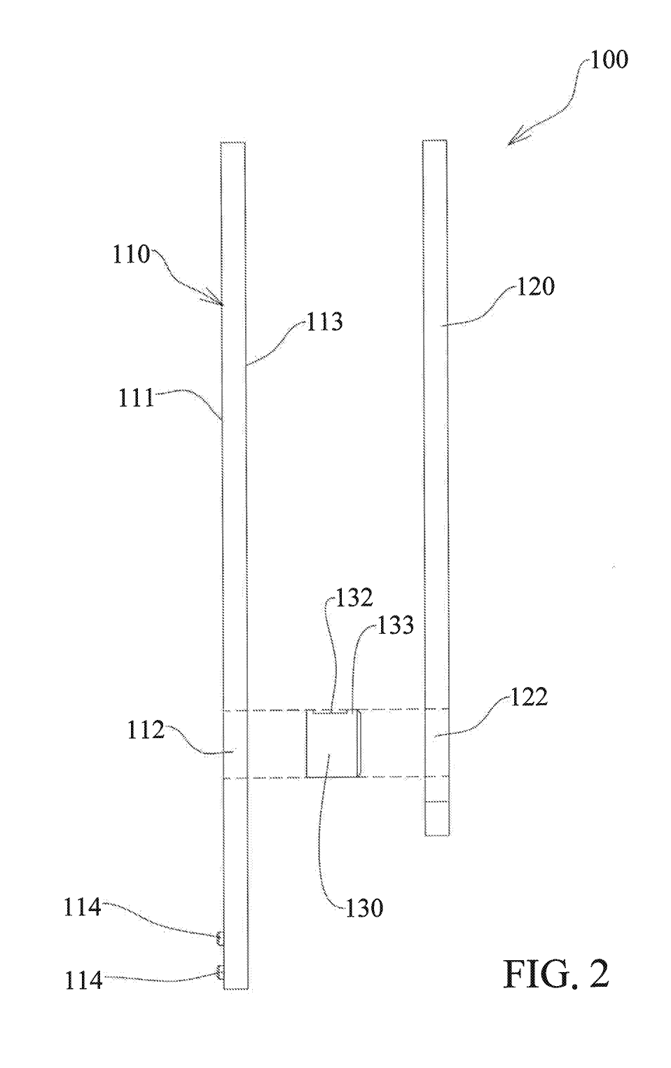

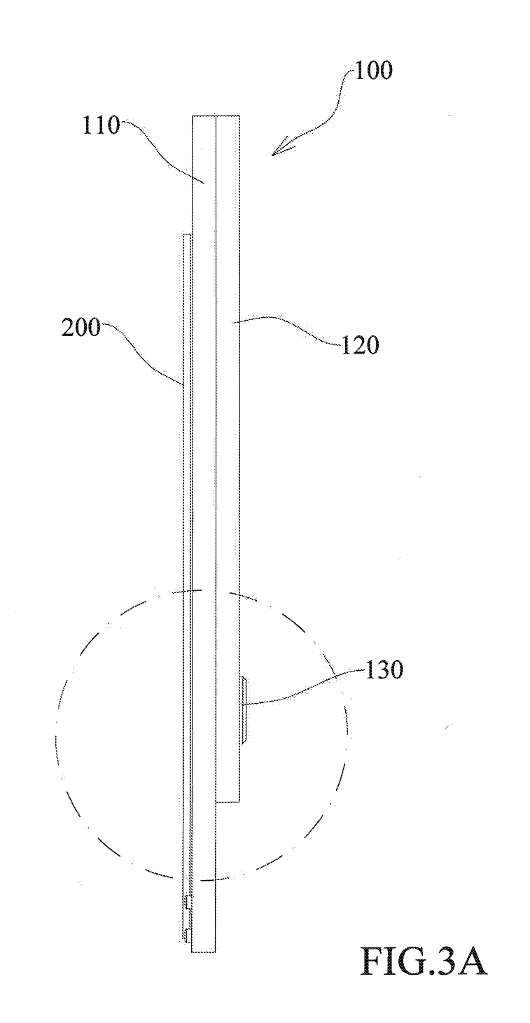

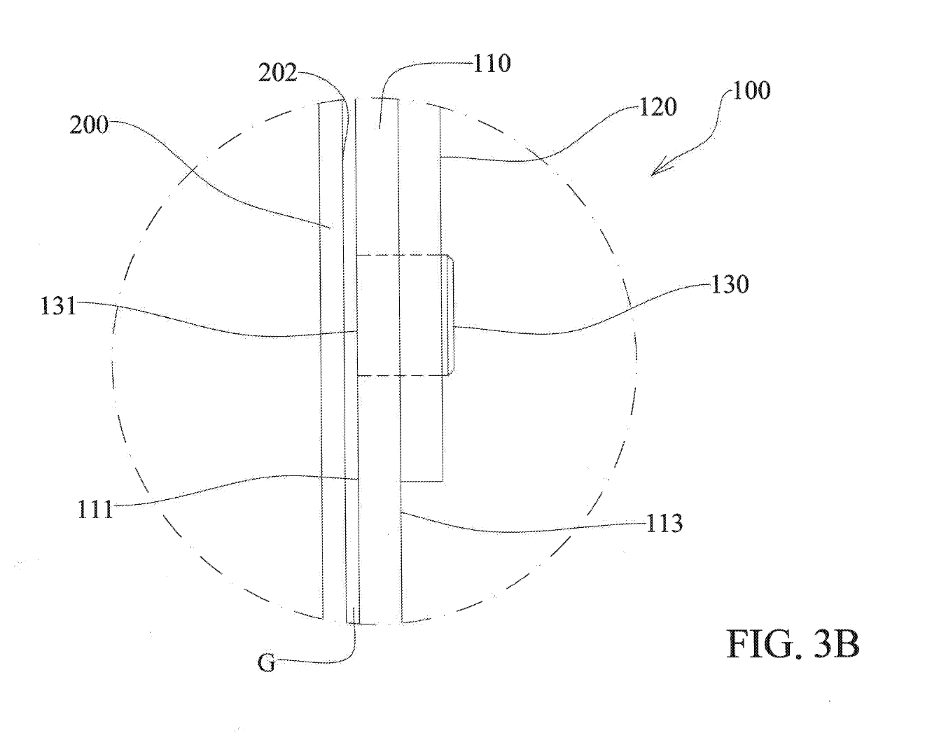

Refer to FIG. 1 and FIG. 2 respectively a diagram and a side view of a non-contact substrate chuck according to one embodiment of the present invention. As shown in FIG. 1, the non-contact substrate chuck 100 of the present invention is used to suck and hold a substrate 200, wherein the substrate 200 may be but is not limited to be an ordinary printed circuit board; and the shape of the substrate 200 may be but is not limited to be a rectangle. The non-contact substrate chuck 100 comprises a first plate-like element 110, a second plate-like element 120 and a sucking element 130. Refer to FIG. 2 for the detailed structure of the non-contact substrate chuck 100. The first plate-like element 110 includes a first through hole 112 penetrating the first plate-like element 110 and a plurality of positioning protrusions 114 arranged on a first surface 111 of the first plate-like element 110. As shown in FIG. 1, the positioning protrusions 114 are used to position the substrate 200. The second plate-like element 120 is arranged parallel to the first plate-like element 110 and on a second surface 113 of the first plate-like element 110. The second plate-like element 120 includes a second through hole 122 penetrating the second plate-like element 120 and cooperating with the first through hole 112 to form a channel (not shown in the drawings) accommodating the sucking element 130. A side view of the assemblage of the first plate-like element 110, the second plate-like element 120 and the sucking element 130 is illustrated in FIG. 3A. Moreover, referring to FIG. 2 and FIG. 3B a locally enlarged view of FIG. 3A, an active surface 202 of the substrate 200 faces the first surface 111 of the first plate-like element 110, and the non-contact substrate chuck 100 lets gas flow through a gas inlet 132 toward the substrate 200 to form a gap G between the active surface 202 of the substrate 200 and the first surface 111, Further, at least one of the sides 201, 203 and 205 of the substrate 200 is positioned by the plurality of positioning protrusions 114, as shown in FIG. 1.

Continuing the above description, referring still to FIG. 3B. In one embodiment, the sucking element 130, such as a non-contact sucker, can form a vacuum suction force between the active surface 202 of the substrate 200 and the sucking element 130, and positive pressure is supplied to the sucking element 130 and makes the substrate 200 attracted by the sucking element 130 to suspend in the air, whereby a gap G is formed between the active surface 202 of the substrate 200 and the first plate-like element 110. It can be understood by a person skilled in the art that the channel where the vacuum suction force is formed by the sucking element 130 differs from the gas inlet where the positive pressure is supplied, hence the repetitious details need not be given here. According to the above-mentioned structure, the active surface 202 of the substrate 200 is sucked and held by the non-contact substrate chuck 100 contactlessly and fabricated by the required processes, not contacting the sucking element 130. In one embodiment, the non-contact substrate chuck 100 supports and holds the substrate 200 to facilitate a wet chemical process without contacting the active surface 202 of the substrate 200. In this embodiment, the non-contact substrate chuck 100 is arranged vertically for space-saving purpose, whereby is favored a batch type process involving a massive quantity of substrates 200 submerged in a chemical liquid tank, and whereby is effectively increased the output for an identical interval of working time.

In the abovementioned embodiment, the sucking element 130 is a cylinder, as illustrated in FIG. 2, and the gas inlet 132 is formed on a cylinder wall 133. After the non-contact substrate chuck 100 has been assembled, a first circular surface 131 of the cylinder and the first surface 111 of the first plate-like element 110 are on the same plane, as shown in FIG. 3B; and the size of the first circular surface 131 of the cylinder matches the size of the first through hole 112 of the first plate-like element 110, as illustrated in FIG. 1. In one embodiment, the first plate-like element 110 and the second plate-like element 120 are fabricated into a one-piece component.

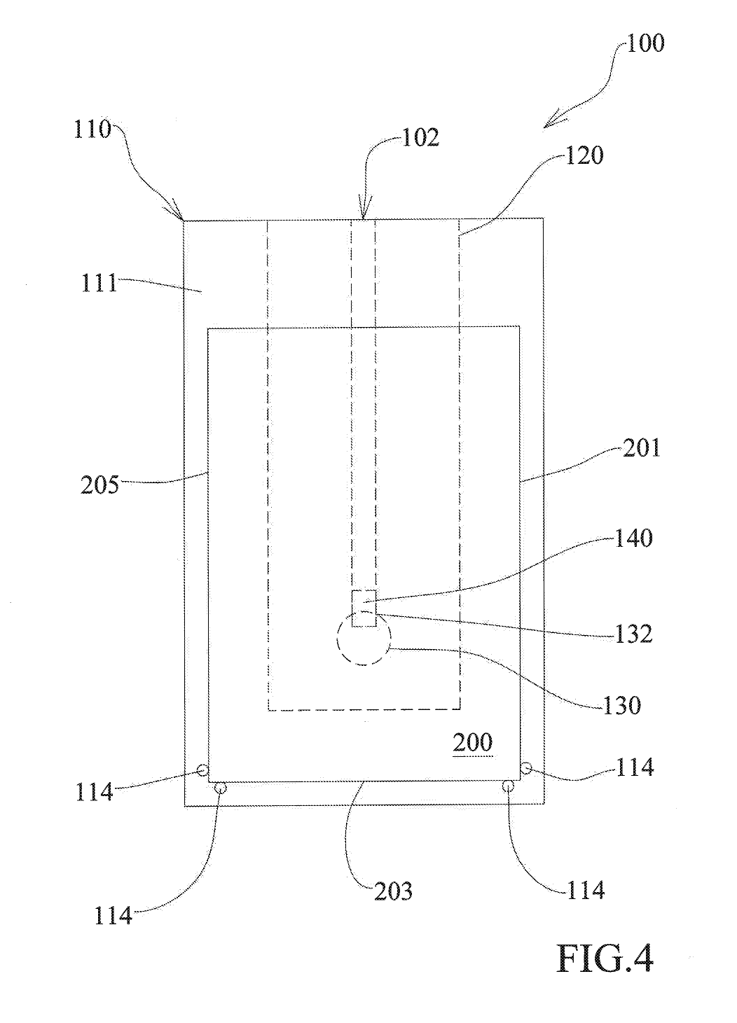

Refer to FIG. 4 a diagram schematically showing a non-contact substrate chuck according to another embodiment of the present invention. In this embodiment, a first airflow channel 102 is formed between the first plate-like element 110 and the second plate-like element 120, and a connector 140 is accommodated by the first airflow channel 102 and partially inserted into the gas inlet 132, whereby positive-pressure gas passes through the first airflow channel 102 and the connector 140 to the sucking element 130.

In the abovementioned embodiments, the substrate may be but is not limited to be an ordinary printed circuit board. In addition, the substrate may be a wafer or chip having a fragile surface or containing circuits on the surface thereof. In the abovementioned embodiments, one surface of the substrate faces the first surface of the first plate-like element; the non-contact substrate chuck lets gas flow through the gas inlet of the sucking element toward the substrate to form a gap between the surface of the substrate and the first substrate; and at least one side of the substrate is positioned by a plurality of positioning protrusions.

It should be understood that the shapes of the first plate-like element, the second plate-like element and the positioning protrusions may be but is not limited to be the shapes shown in the drawings of the specification. No matter what shape the component is designed to have, a substrate chuck would be also included within the scope of the present invention, as long as the sucking element thereof faces but does not contact the surface/active surface of the substrate and the plate-like element thereof facing the surface/active surface of the substrate has positioning protrusions to position the sides of the substrate.

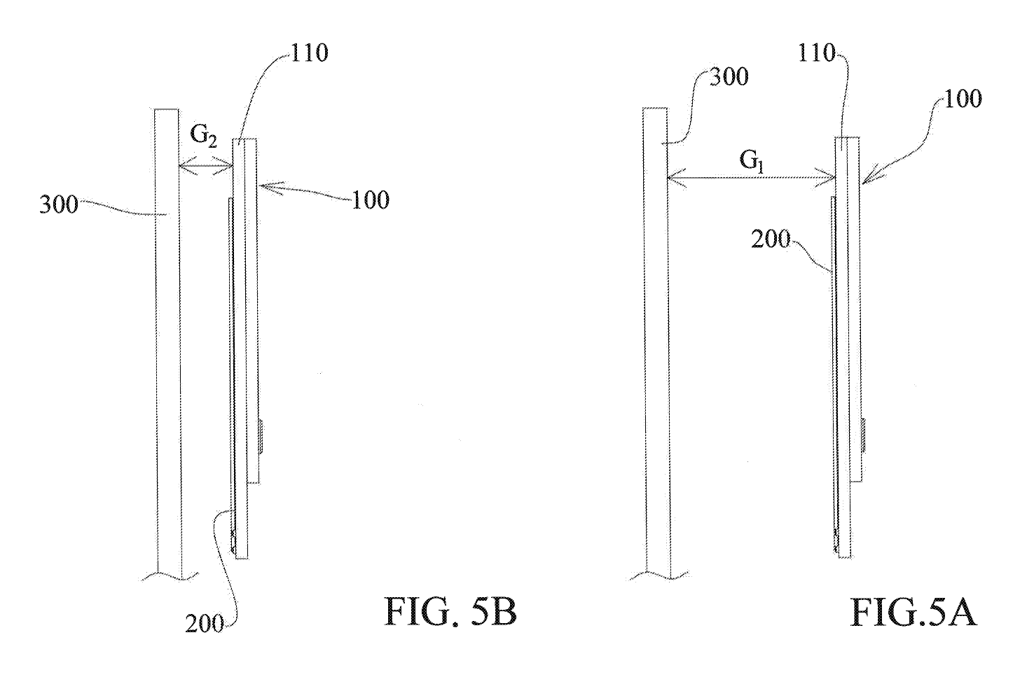

Refer to FIG. 5A and FIG. 5B side views of a vertical type substrate supporting apparatus according to yet another embodiment of the present invention. In this embodiment, the vertical type substrate supporting apparatus comprises a non-contact substrate chuck 100 described above and a fixture 300. As illustrated in FIG. 5A, the fixture 300 is arranged on one side near the first plate-like element 110 of the non-contact substrate chuck 100 and separated from the non-contact substrate chuck 100 by a first spacing G₁. When the spacing between the fixture 300 and the non-contact substrate chuck 100 is decreased to a second spacing G₂ (as shown in FIG. 5B), the fixture 300 moves the substrate 200 (or a wafer) to or off the first plate-like element 110 of the non-contact substrate chuck 100. The magnitude of the second spacing G₂ depends on the design of the fixture 300. The spacing is decreased via moving the non-contact substrate chuck 100, the fixture 300, or both,

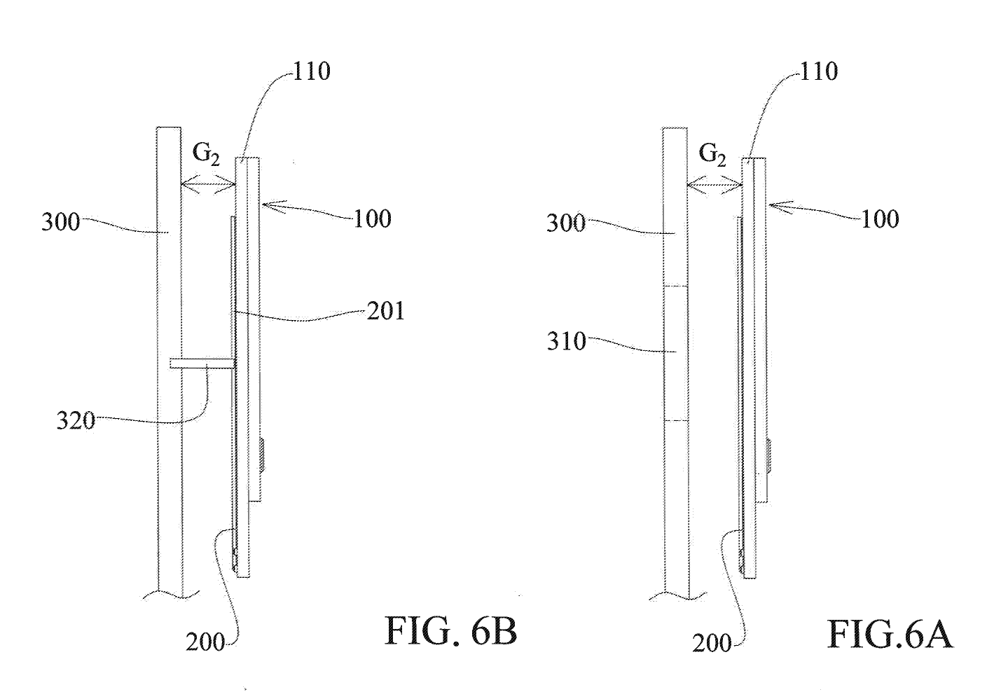

Continuing the above description, referring to FIG. 6A and FIG. 6B which are side views of a vertical type substrate supporting apparatus according to a further embodiment of the present invention. In this embodiment, the fixture 300 of the vertical type substrate supporting apparatus includes a sucking member 310 (as shown in FIG. 6A) or a holding member 320 (as shown in FIG. 6B). In one embodiment, as illustrated in FIG. 6A, the sucking member 310 sucks the substrate 200 (or a wafer) and holds the substrate 200 in a contact way or a non-contact way. If the active surface of the substrate 200 faces the sucking member 310, the sucking member 310 sucks and holds the active surface of the substrate 200 in a gap way as the non-contact substrate chuck 100 uses. Contrarily, the sucking member 310 may suck and hold the surface of the substrate 200 in a contact way or a gap way to place the substrate 200 on the non-contact substrate chuck 100 or take the substrate 200 from the non-contact substrate chuck 100. In another embodiment, as illustrated in FIG. 6B, the fixture 300 has a holding member 320. The holding member 320 holds the sides 201 of the substrate 200 to move the substrate 200 to or off the non-contact substrate chuck 100.

The present invention is characterized in that the non-contact substrate chuck is vertically arranged to save space, favor batch type mass production, and enhance the output for an identical interval of working time.

In conclusion, the present invention provides a non-contact substrate chuck and a vertical type substrate supporting apparatus using the same, wherein the substrate chuck does not contact the surface of the substrate and uses a least possible number of supporting points arranged around the unessential sides of the substrate to prevent the substrate surface from being damaged.

What is claimed is:

1. A non-contact substrate chuck, which applies to sucking and holding a substrate and comprises:
a first plate-like element including a first through hole penetrating said first plate-like element and a plurality of positioning protrusions on a first surface of said first plate-like element;
a second plate-like element arranged parallel to said first plate-like element and on a second surface of said first plate-like element, wherein a second through hole penetrating said second plate-like element and cooperating with said first through hole to form a channel; and
a sucking element arranged inside said channel, wherein an active surface of said substrate faces said first surface of said first plate-like element, and wherein said non-contact substrate chuck lets gas flow through a gas inlet of said sucking element toward said substrate to form a gap between said active surface and said first surface; and at least one side of said substrate is positioned by said positioning protrusions.

2. The non-contact substrate chuck according to claim 1, which is arranged vertically.

3. The non-contact substrate chuck according to claim I, wherein a first airflow channel is formed between said first plate-like element and said second plate-like element, and wherein a connector is accommodated by said first airflow channel and partially inserted into said gas inlet.

4. The non-contact substrate chuck according to claim 1, wherein said sucking element is a cylinder, and wherein a first circular surface of said cylinder and said first surface of said first plate-like element are on an identical plane.

5. The non-contact substrate chuck according to claim 1, wherein said gas inlet is formed on a cylinder wall of said sucking element.

6. The non-contact substrate chuck according to claim 1, wherein said first plate-like element and said second plate-like element are fabricated into a one-piece component.

7. A vertical-type substrate supporting apparatus comprising the non-contact substrate chuck according to claim 1 and a fixture, wherein said fixture is arranged on one side near said first plate-like element of said non-contact substrate chuck and separated from said non-contact substrate chuck by a first spacing, and wherein while said first spacing between said fixture and said non-contact substrate chuck is decreased to a second spacing, said fixture moves said substrate to or off said first plate-like element of said non-contact substrate chuck.

8. The vertical-type substrate supporting apparatus according to claim 7, wherein said fixture includes a sucking member or a holding member.

9. The vertical-type substrate supporting apparatus according to claim 8, wherein said sucking member sucks said substrate and holds said substrate in a contact way or a non-contact way, and wherein said holding member holds sides of said substrate.

10. A non-contact substrate chuck, which applies to sucking and holding a substrate and comprises:
a first plate-like element including a first through hole penetrating said first plate-like element and a plurality of positioning protrusions on a first surface of said first plate-like element;
a second plate-like element arranged parallel to said first plate-like element and on a second surface of said first plate-like element and including a second through hole penetrating said second plate-like element and cooperating with said first through hole to form a channel; and
a sucking element arranged inside said channel, wherein a surface of said substrate faces said first surface of said first plate-like element, and wherein said non-contact substrate chuck lets gas flow through a gas inlet of said sucking element toward said substrate to form a gap between said surface of said substrate and said first surface, and wherein at least one side of said substrate is positioned by said positioning protrusions.

11. A vertical-type substrate supporting apparatus comprising the non-contact substrate chuck according to claim 10 and a fixture, wherein said fixture is arranged on one side near said first plate-like element of said non-contact substrate chuck and separated from said non-contact substrate chuck by a first spacing, and wherein while said first spacing between said fixture and said non-contact substrate chuck is decreased to a second spacing, said fixture moves said substrate to or off said first plate-like element of said non-contact substrate chuck.
